(19) United States
(12) Patent Application Publication
(10) Pub. No.: US 2026/0271238 A1
(43) Pub. Date: Sep. 10, 2026

(54) COOLING STRUCTURE FOR ELECTRONIC COMPONENT

(71) Applicant: SEA SONIC ELECTRONICS CO., LTD., Taipei City (TW)

(72) Inventor: Chi-Hao CHANG, Taipei City (TW)

(21) Appl. No.: 19/070,943

(22) Filed: Mar. 5, 2025

(51) Int. Cl. H05K 7/20; H05K 1/02

(52) U.S. Cl. CPC H05K 7/20463; H05K 1/0204; H05K 7/20409; H05K 7/20481

(57) ABSTRACT

A cooling structure for electronic component includes an electronic component, a heat sink, and a circuit board. The electronic component includes a package casing, a plurality of pins exposed from the package casing, and a top-mounted heat sink exposed from the package casing. The heat sink is formed with a space for accommodating the electronic component and an injection channel communicating with the space. A physical thermal conducting medium is injected into the space through the injection channel, and the physical thermal conducting medium facilitates thermal conduction between the top heat sink and the heat sink. The circuit board is provided with a plurality of first copper coils for bonding the pins, and a second copper coil for bonding the heat sink. Further, the electronic component in the invention can be implemented in multiple configurations, and the electronic components can be arranged in parallel.

### FIELD OF THE INVENTION

The invention relates to a cooling structure, specifically the

### BACKGROUND OF THE INVENTION

Electronic components tend to generate waste heat when in operation, so manufacturers mostly use heat sinks to dissipate heat from electronic components. Among them, the conventional technology of attaching heat sinks is to lock the heat sink to the electronic component so that the heat sink directly contacts the electronic component for heat conduction. On the other hand, a thermal conducting medium can be applied to the surface of the electronic component, and then a heat sink can be positioned at the location of the electronic component to fill the gap between the electronic component and the heat sink with the thermal conducting medium, thereby forming a path for the electronic component to conduct heat to the heat sink.

Accordingly, TWM320289U provides an improved surface-mounted heat dissipation structure which includes a circuit board, a heat dissipation element, and a thermal conductive adhesive. The heat dissipation element includes a heat dissipation cover body with a pouring hole and an accommodating space provided for a light-emitting element to be arranged therein. TWM320289U discloses that the light emitting element is soldered to the circuit board and electrically connected to a copper foil on the circuit board. The heat dissipation cover is embedded on one side of the light emitting element, so that the light emitting element is located in the accommodation space of the heat dissipation element. A thermal conductive adhesive is injected into the injecting hole, enabling effective heat conduction for the light emitting element.

On the other hand, the technology of TWM320289U requires the heat dissipation element to be embedded with the electronic component, rather than simply being positioned by bonding it to the circuit board. This makes it difficult to implement in practice when trying to further increase the production capacity of electronic components through automated operations. Furthermore, the conventional technology of attaching the heat sink is more complicated in terms of locking method, and is not conducive to the implementation of automated operation.

### SUMMARY OF THE INVENTION

A main object of the invention is to solve the problem that conventional cooling structures are inconvenient to be installed during automated operations.

Another object of the invention is to improve the cooling effect of a cooling structure for electronic component.

In order to achieve the above object, the invention provides a cooling structure for electronic component, comprising an electronic component, a heat sink, and a circuit board. The electronic component includes a package casing, a plurality of pins exposed from the package casing, a top-mounted heat sink exposed from the package casing. The heat sink is formed with a space for accommodating the electronic component and an injection channel communicated with the space, a physical thermal conducting medium being injected into the space through the injection channel, and the physical thermal conducting medium facilitating thermal conduction between the top-mounted heat sink and the heat sink. The circuit board is provided with a plurality of first copper foils and a second copper foil, the first copper foils are provided for bonding the pins of the electronic component, and the second copper foil is provided for bonding the heat sink.

In one example, the heat sink comprises a plurality of fins, and the injection channel is formed on one of the fins.

In one example, the injection channel is provided with a first port exposed from the heat sink and a second port facing the space, the second port is larger than the first port.

In one example, the injection channel includes an injection section communicated with the first port, and a gradually expanding section communicated with the injection section and the second port.

In one example, the heat sink is formed with an accommodating groove, the accommodating groove is a part of the space and is communicated with the second port.

In one example, the second copper coil is divided into at least one first portion for bonding the heat sink, and a second portion connected to the at least one first portion, the second portion is in contact with the package casing of the electronic component without forming a bonding connection.

In one example, the heat sink is straddled on the electronic component, the heat sink comprises two bonding feet, the second copper foil comprises two first portions, and the second portion of the second copper foil is positioned between the two first portions.

In one example, the space of the heat sink is formed by a notch.

In one example, the heat sink is formed with an accommodating groove, which is a part of the space and is connected to the second port.

In one example, at least one of the two first portions includes a heat sink bonding area and an auxiliary cooling area connected to the heat sink bonding area.

In one example, the first copper foils are divided into two groups spaced apart, at least three sides of each of the two groups are provided with the second copper foil, and the second portion of the second copper foil is positioned between the two groups.

In one example, each of the two first portions includes a heat sink bonding area and two auxiliary cooling areas connected to the heat sink bonding area.

In one example, the cooling structure for electronic component includes a plurality of electronic components, and the space of the heat sink is provided for accommodating the electronic components.

In one example, the cooling structure for electronic component includes a plurality of electronic components, the heat sink is formed with a plurality of spaces and a plurality of injection channels, each of the injection channels corresponding to one of the spaces, the electronic components are respectively arranged in the spaces, and a number of electronic components arranged in each of the spaces is greater than or equal to one.

Through the above-mentioned implementation of the present invention, compared with the conventional method, the following characteristics are possessed: the second copper foil in the invention not only serves as an adhesion point of the heat sink during an automated operation but also acts as a cooling pathway. The heat sink is provided with an injection channel, allowing the physical thermal conducting medium to be injected into the space. The overall structure of this invention requires only simple positioning, adhesion, and injection operations during the automated operation, making it more suitable for automation compared to conventional methods. Additionally, the disclosed structure significantly enhances cooling efficiency. The cooling structure for electronic component in the invention is not limited to a single electronic component, but can be implemented in multiple configurations, and the heat sink can be adjusted accordingly based on implementation needs.

### BRIEF DESCRIPTION OF THE DRAWINGS

FIG. 1 is a schematic structural diagram of the first example of a cooling structure for electronic component of the invention.

FIG. 2 is an exploded structural diagram of the first example of a cooling structure for electronic component of the invention.

FIG. 3 is a top-view schematic diagram of a partial structure of the first example of a cooling structure for electronic component of the invention.

FIG. 4 is a first cross-sectional diagram of the first example of a cooling structure for electronic component of the invention.

FIG. 5 is a second cross-sectional diagram of the first example of a cooling structure for electronic component of the invention.

FIG. 6 is a third cross-sectional diagram of the first example of a cooling structure for electronic component of the invention.

FIG. 7 is a cross-sectional diagram of the second example of a cooling structure for electronic component of the invention.

FIG. 8 is a cross-sectional diagram of the third example of a cooling structure for electronic component of the invention.

FIG. 9 is a schematic structural diagram of the fourth example of a cooling structure for electronic component of the invention.

FIG. 10 is a schematic structural diagram of a copper foil in the fourth example of a cooling structure for electronic component of the invention.

### DETAILED DESCRIPTION OF THE PREFERRED EMBODIMENTS

The detailed description and technical content of the invention are as follows, with reference to the accompanying figures:

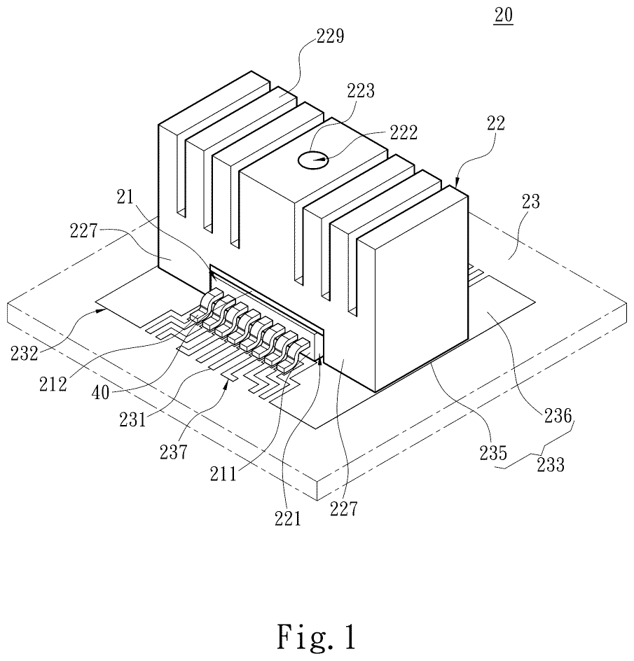

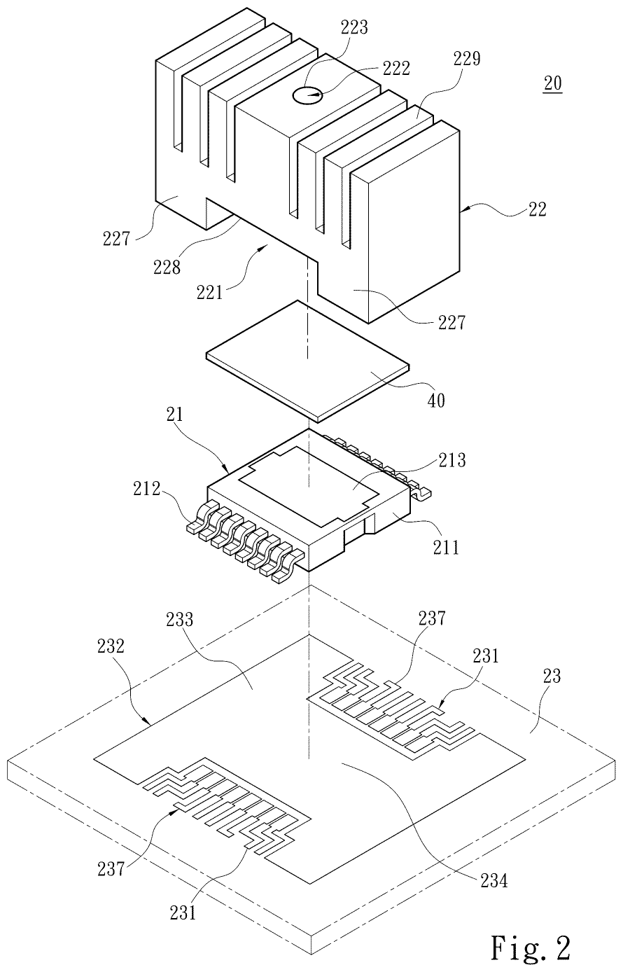

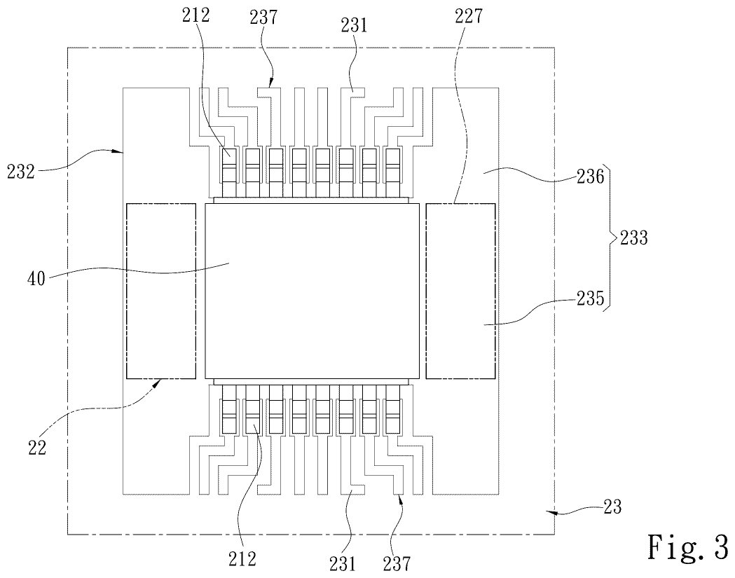

Please refer to FIG. 1, FIG. 2, and FIG. 3. The invention provides a cooling structure for electronic component 20 comprising an electronic component 21, a heat sink 22, and a circuit board 23. The electronic component 21 may apply to a surface mount technology (SMT). The electronic component 21 includes a package casing 211, a plurality of pins 212 exposed from the package casing 211, and a top-mounted heat sink 213 exposed from the package casing 211. Appearances of the package casing 211 and the pins 212 can be adjusted according to usage requirements. The heat sink 22 is formed with a space 221 for accommodating the electronic component 21 and an injection channel 222 that communicates with the space 221. The injection channel 222 is provided for injection a physical thermal conducting medium 40 into the space 221, and the physical thermal conducting medium 40 facilitates thermal conduction between the top-mounted heat sink 213 and the heat sink 22. To further explain, the position of “top-mounted” of the top-mounted heat sink 213 refers to an upper surface of the top-mounted heat sink 213 away from the circuit board 23 after the electronic component 21 is mounted on the circuit board 23. The top-mounted heat sink 213 may partially cover or fully cover the upper surface of the electronic component 21 not facing the circuit board 23. On the other hand, after the physical thermal conducting medium 40 fills with the space 221, thermal conduction between the top-mounted heat sink 213 and the heat sink 22 is facilitated. Moreover, thermal conduction further occurs between the package casing 211 and the heat sink 22 through the physical thermal conducting medium 40, which can be a heat dissipating paste or a heat dissipating adhesive. The circuit board 23 is provided with a plurality of first copper foils 231 and a second copper foil 232, the first copper foils 231 are provided for bonding the pins 212 of the electronic component 21, and the second copper foil 232 is provided for bonding the heat sink 22.

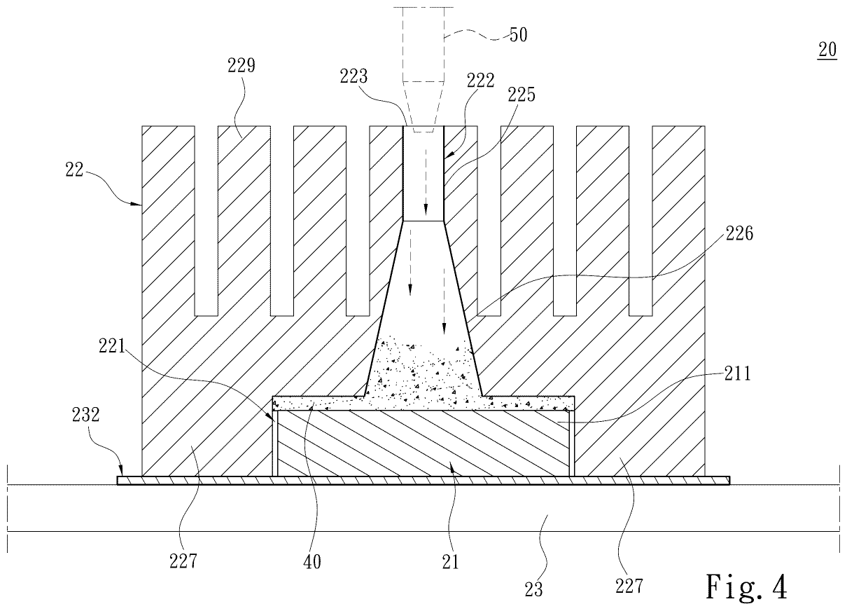

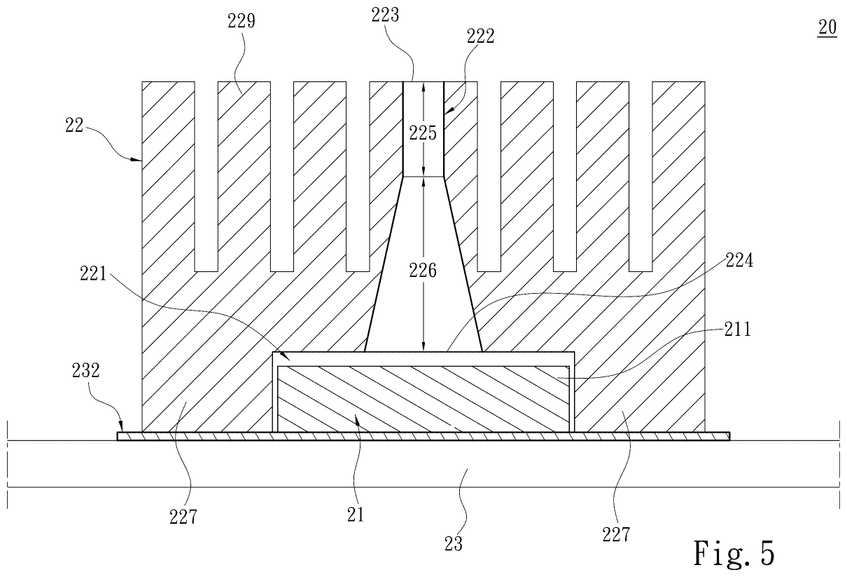

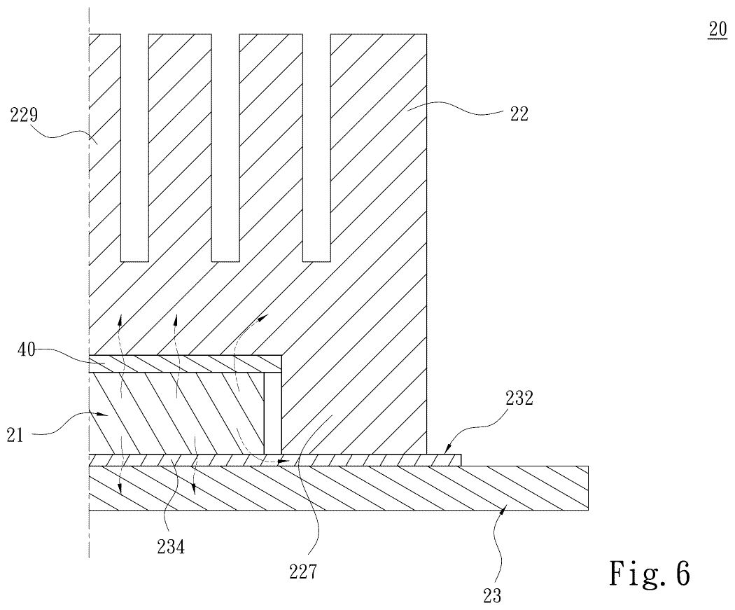

Please refer to FIG. 2, FIG. 3, FIG. 4, FIG. 5, and FIG. 6, the implementation of the cooling structure for electronic component 20 will now be described. When the cooling structure for electronic component 20 is installed by an automated operation, the pins 212 of the electronic component 21 are first bonded to the first copper foils 231. Next, the heat sink 22 is placed at a position corresponding to the electronic component 21 and bonded to the second copper coil 232. At this time, the electronic component 21 is positioned in the space 221 of the heat sink 22, as shown in FIG. 5. Then, the physical thermal conducting medium 40 is injected into the injection channel 222 by an injection structure 50 during the automated operation. The physical thermal conducting medium 40 is in contact with the heat sink 22 and the electronic component 21 to form thermal conduction while being injected into the space 221, as shown in FIG. 4. In this way, installation of the cooling structure for electronic component 20 is completed. As can be seen from the foregoing, the automated assembling of the cooling structure for electronic component 20 of the invention only requires simple positioning, bonding and injection operations. The aforementioned operation can be performed mechanically and automatically, which is more conducive to automated implementation than the conventional method that requires additional manual locking or embedding. Furthermore, during implementation, the waste heat generated by the electronic component 21 can be dissipated through the heat sink 22. In addition, the heat generated at a position of the electronic component 21 can also be dissipated through the heat sink 22 while being conducted to the circuit board 23, guided by the second copper foil 232. Therefore, the cooling structure for electronic component 20 of the invention not only facilitates automated implementation but also enhances the overall cooling effect.

Please refer to FIG. 4. In an example, the injection channel 222 includes a first port 223 exposes from the heat sink 22 and a second port 224 facing the space 221. The second port 224 is larger than the first port 223. The invention increases a flow range of the physical thermal conducting medium 40 into the space 221 through the design of the second port 224, thereby preventing the physical thermal conducting medium 40 from excessively gathering at a single position. In an example, the injection channel 222 may include an injection section 225 communicated with the first port 223, and a gradually expanding section 226 communicated with the injection section 225 and the second port 224. The injection channel 222 does not have a change in diameter at the injection section 225. The implementation of the gradually expanding section 226 facilitates the injection of the physical thermal conducting medium 40 and avoids the impact of the channel design with the single diameter on the injection.

Please refer to FIG. 4 and FIG. 5. In an example, the second copper foil 232 is divided into at least one first portion 233 for bonding the heat sink 22, and a second portion 234 connected to the at least one first portion 233. The second portion 234 contacts the package casing 211 of the electronic component 21 but does not form a bonding connection. Further, when the second copper foil 232 is positioned, in addition to being disposed adjacent to the first copper foils 231, the second portion 234 of the second copper foil 232 is located at a predetermined position for placing the electronic component 21. The second portion 234 does not serve to secure the electronic component 21 but rather provides a placement area for the package casing 211 of the electronic component 21, forming a thermal conduction relationship.

Please refer to FIG. 2, FIG. 3, FIG. 4, FIG. 5, and FIG. 6. In an example, when the cooling structure for electronic component 20 is installed by an automated operation, the pins 212 of the electronic component 21 are first bonded to the first copper foils 231. At the same time, the second portion 234 is positioned beneath the electronic component 21 and is in contact with the package casing 211 of electronic component 21. Next, the heat sink 22 is positioned to correspond with the electronic component 21 and is bonded to at least one first portion 233 of the second copper foil 232. The electronic component 21 is positioned in the space 221 of the heat sink 22, as shown in FIG. 5. Lastly, the physical thermal conducting medium 40 is injected into the space 221 through the injection channel 222, so that the physical thermal conducting medium 40 is positioned in the space 221 contacting the heat sink 22 and the electronic component 21, forming the thermal conduction relationship, as shown in FIG. 4. In this example, the second copper foil 232 is provided to allow the electronic component 21 to dissipate heat in various approaches. For example, the aforementioned various approaches can lead the waste heat from the electronic component 21 to the heat sink 22 through the physical thermal conducting medium 40, so that the heat sink 22 can exchange heat with the outside. In addition to the above, the waste heat can also be guided from the electronic component 21 to the second portion 234 of the second copper coil 232, and then guided from the second portion 234 to the at least one first portion 233. When the waste heat is introduced into the at least one first portion 233, the waste heat can be conducted to the circuit board 23 or the heat sink 22. The various approaches illustrated above can be implemented simultaneously, as shown in FIG. 6. As a result, the cooling structure for electronic component 20 of the invention has better cooling efficiency for the electronic component 21 compared with the convention one.

Please refer to FIG. 2, FIG. 3, FIG. 4, FIG. 5, and FIG. 6. In an example, the heat sink 22 includes two bonding feet 227, the second copper foil includes two first portions 233, and the second portion 234 of the second copper foil 232 is positioned between the two second portions 233. Specifically, the two bonding feet 227 of the heat sink 22 is positioned corresponding to the two first portions 233, and the two first portions 233 are respectively positioned at two opposite sides of the second portion 234, so that after the cooling structure for electronic component 20 is assembled, the heat sink 22 is straddle on the electronic component 21. In addition, in another example, the space 221 on the heat sink 22 is formed by a notch 228. The two bonding feet 227 are respectively formed on two sides of the notch 228. When the heat sink 22 is positioned during the automated operation, the notch 228 can be arranged at the position of the electronic component 21, and the two bonding feet 227 can be arranged on the two first portions 233, ensuring more precise placement and positioning of the heat sink 22.

In another example, at least one of the two first portions 233 includes a heat sink bonding area 235 and an auxiliary cooling area 236. The auxiliary cooling area 236 does not contact to the electronic component 21 and the heat sink 22, the auxiliary cooling area 236 increases an area of the second copper foil 232 for direct heat exchange with the outside. When the heat sink bonding area 235 receives the waste heat transferred by the second portion 234, the heat sink bonding area 235 can transfer the waste heat to the auxiliary cooling area 236, and the auxiliary cooling area 236 directly exchanges heat with the outside to improve cooling efficiency of the cooling structure for electronic component 20. Further, in another example, each of the two first portions 233 includes a heat sink bonding area 235 and two auxiliary cooling areas 236 connected to the heat sink bonding area 235. The heat sink bonding area 235 is positioned between the two auxiliary cooling areas 236, so that each of the two first portions 233 has the auxiliary cooling effect provided by the two auxiliary cooling areas 236.

Please refer to FIG. 3, FIG. 4, FIG. 5, and FIG. 6. In an example, the first copper foils are divided into two groups 237 spaced apart, each of the two groups 237 is positioned facing the second portion 234 of the second copper foil 232, and the pins 212 of the electronic component 21 are bonded to positions of the two groups 237. In another example, at least three sides of each of the two groups 237 are provided with the second copper coil 232, and the second portion 234 of the second copper coil 232 is positioned between the two groups 237. That is to say, each of the two first portions 233 includes the two auxiliary cooling areas 236 respectively positioned on two opposite sides of the heat sink bonding area 235 and facing two of the at least three sides of each of the two groups 237, and the second portion 234 faces one of the at least three sides, forming a configuration where the second copper foil 232 approximately surrounds each of the two groups 237. This arrangement enhances the overall cooling efficiency of the cooling structure for electronic component 20.

In another example, the heat sink includes a plurality of fins 229 extending toward a direction opposite to the electronic component 21 and positioned at intervals. The fins 229 increases an area of the heat sink in contact with the outside to enhance the heat exchange capability of the heat sink 22. The injection channel 222 is formed on one of the fins 229, and the injection channel primarily corresponds to the position of the electronic component 21.

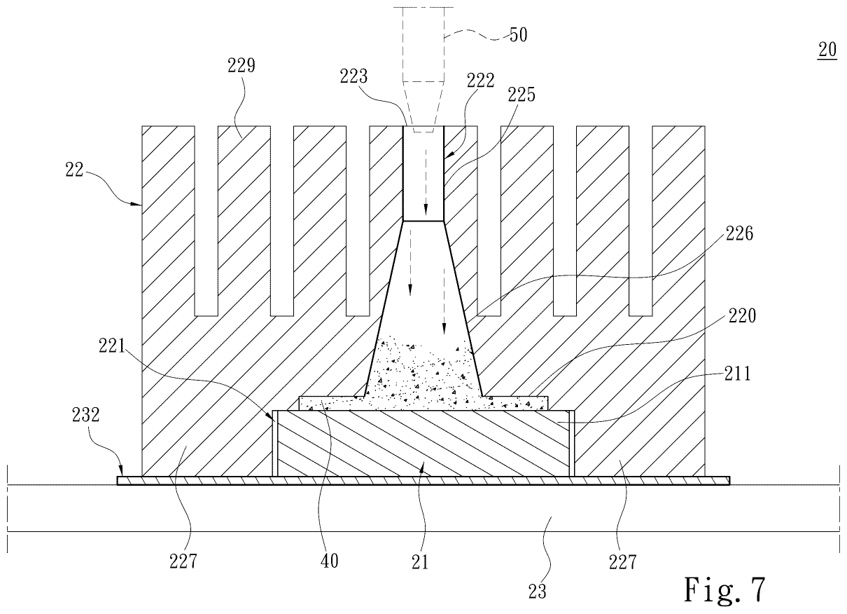

Please refer to FIG. 7. In an example, the heat sink 22 is formed with an accommodating groove 220, which is a part of the space 221 and is connected to the second port 224. After the accommodating groove 220 is positioned in the heat sink 22, the accommodating groove 220 faces the electronic component 21, and a size of an area of the accommodating groove 220 can be adjusted based on an intended contact area between the physical thermal conducting medium 40 and the electronic component 21 to prevent the physical thermal conducting medium 40 from overflowing from the space 221.

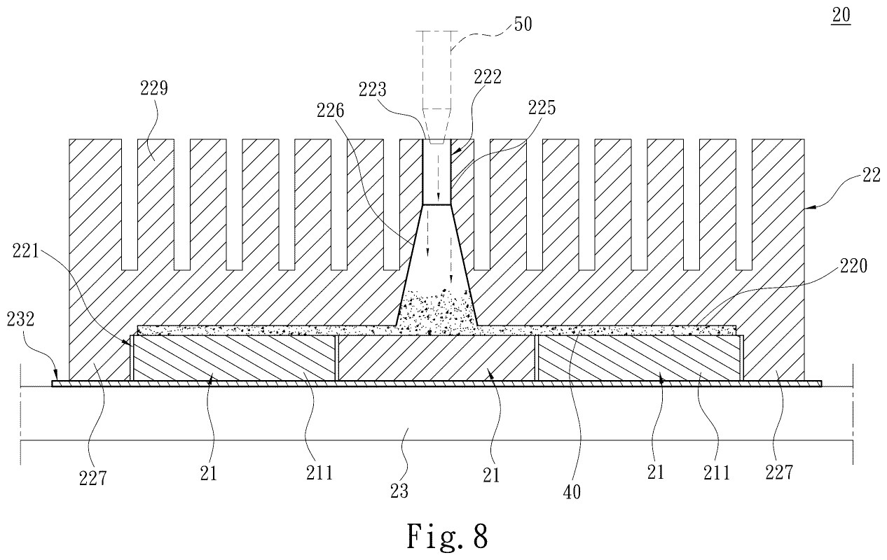

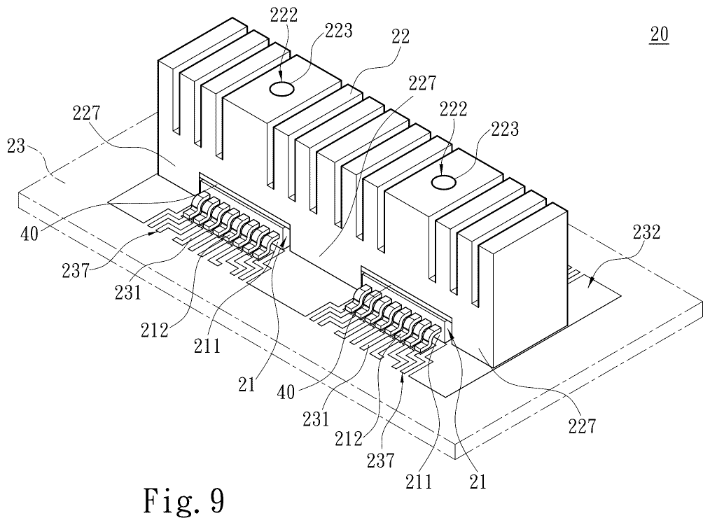

The cooling structure for electronic component 20 in this invention is not limited to providing cooling for a single electronic component 21. In an example, the cooling structure for electronic component 20 includes a plurality of electronic components 21, the space 221 of the heat sink 22 can be designed to accommodate the electronic components 21 simultaneously. The physical thermal conducting medium 40 injected into the space 221 through the injection channel 222 contacts with the electronic components 21 within the space 221, as shown in FIG. 8. In addition to the aforementioned examples, the heat sink 22 can also be formed with a plurality of spaces 221 and a plurality of injection channels 222, as shown in FIG. 9. The spaces 221 are formed at intervals, and portions of the heat sink 22 located between any two adjacent spaces 221 can serve as the two bonding feet 227. Therefore, the circuit board 23 corresponded to positions of the two bonding feet 227 can be a part of the second copper foil 232. In this example, the second copper foil 232 may be slightly fishbone-shaped.

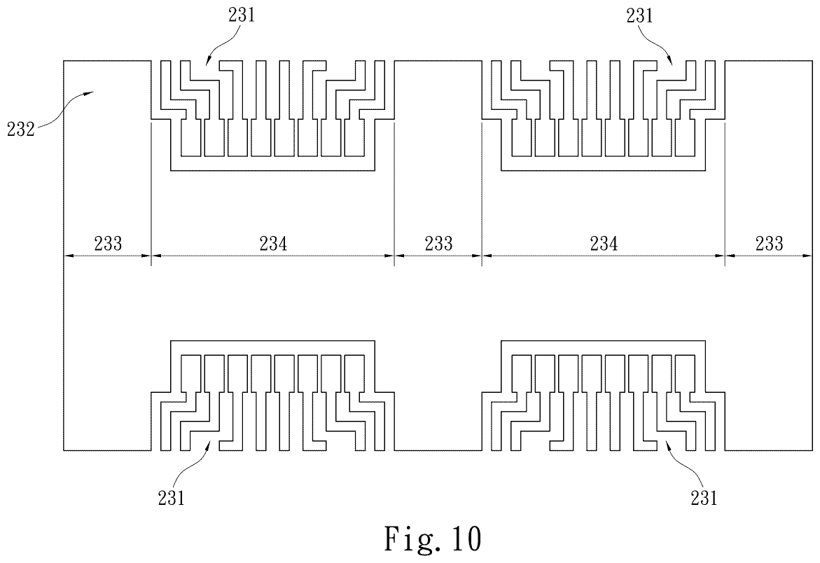

Please also refer to FIG. 10. Based on the differentiation between the first portions 233 and the second portions 234 mentioned earlier, the second copper foil 232 can be sequentially divided into segments as follows: the first portion 233, the second portion 234, the first portion 233, the second portion 234, and the first portion 233. On the other hand, each of the injection channels 222 corresponds to one of the spaces 221, with the electronic components 21 respectively housed within these spaces 221. Furthermore, a number of electronic components 21 arranged in each of the spaces 221 is greater than or equal to one. In other words, a size of each of the spaces 221 can be adjusted according to implementation requirements, allowing each of the spaces 221 to accommodate at least one of the electronic components 21 according to the requirement. Additionally, as mentioned in the previous example, the electronic components 21 are arranged in a parallel circuit configuration.

What is claimed is:

1. A cooling structure for electronic component, comprising:
an electronic component, comprising a package casing, a plurality of pins exposed from the package casing, and a top-mounted heat sink exposed from the package casing:
a heat sink, formed with a space for accommodating the electronic component and an injection channel communicated with the space, a physical thermal conducting medium being injected into the space through the injection channel, and the physical thermal conducting medium facilitating thermal conduction between the top-mounted heat sink and the heat sink; and
a circuit board, comprising a plurality of first copper foils and a second copper foil, the first copper foils provided for bonding the pins of the electronic component, and the second copper foil provided for bonding the heat sink.

2. The cooling structure for electronic component claimed in claim 1, wherein the heat sink comprises a plurality of fins, and the injection channel is formed on one of the fins.

3. The cooling structure for electronic component as claimed in claim 1, wherein the injection channel comprises a first port exposes from the heat sink and a second port facing the space, and the second port is larger than the first port.

4. The cooling structure for electronic component as claimed in claim 3, wherein the injection channel comprises an injection section communicated with the first port, and a gradually expanding section communicated with the injection section and the second port.

5. The cooling structure for electronic component as claimed in claim 4, wherein the heat sink is formed with an accommodating groove, and the accommodating groove is a part of the space and is communicated with the second port.

6. The cooling structure for electronic component as claimed in claim 1, wherein the second copper coil is divided into at least one first portion for bonding the heat sink and a second portion connected to the at least one first portion, and the second portion is in contact with the package casing of the electronic component without forming a bonding connection.

7. The cooling structure for electronic component as claimed in claim 6, wherein the heat sink is straddled on the electronic component, the heat sink comprises two bonding feet, the second copper foil comprises two first portions, and the second portion of the second copper foil is positioned between the two first portions.

8. The cooling structure for electronic component as claimed in claim 7, wherein the space of the heat sink is formed by a notch.

9. The cooling structure for electronic component as claimed in claim 7, wherein at least one of the two first portions comprises a heat sink bonding area and an auxiliary cooling area connected to the heat sink bonding area.

10. The cooling structure for electronic component as claimed in claim 6, wherein the first copper foils are divided into two groups spaced apart, at least three sides of each of the two groups are provided with the second copper foil, and the second portion of the second copper foil is positioned between the two groups.

11. The cooling structure for electronic component as claimed in claim 6, wherein each of the at least one first portion comprises a heat sink bonding area and two auxiliary cooling areas connected to the heat sink bonding area.

12. The cooling structure for electronic component as claimed in claim 1, wherein the space of the heat sink is formed by a notch.

13. The cooling structure for electronic component as claimed in claim 1, wherein the cooling structure for electronic component comprises a plurality of electronic components, and the space of the heat sink is provided for accommodating the electronic components.

14. The cooling structure for electronic component as claimed in claim 1, wherein the cooling structure for electronic component comprises a plurality of electronic components, the heat sink is formed with a plurality of spaces and a plurality of injection channels, each of the injection channels corresponds to one of the spaces, the electronic components are respectively arranged in the spaces, wherein a number of electronic components arranged in each of the spaces is greater than or equal to one.
